(19) United States
(12) Patent Application Publication
(10) Pub. No.: US 2019/0068213 A1
(43) Pub. Date: Feb. 28, 2019

(54) REFERENCE VOLTAGE STABILIZING CIRCUIT AND INTEGRATED CIRCUIT PROVIDED WITH SAME

(71) Applicant: SOCIONEXT INC., Yokohama-Shi (JP)

(72) Inventors: Daisuke NOMASAKI, Yokohama-Shi (JP); Takashi MORIE, Yokohama-Shi (JP)

(21) Appl. No.: 16/157,741

(22) Filed: Oct. 11, 2018

Related U.S. Application Data
(63) Continuation of application No. PCT/JP2017/006354, filed on Feb. 21, 2017.

(30) Foreign Application Priority Data
Apr. 13, 2016 (JP) 2016-080597

(51) Int. Cl. H03M 1/38; G05F 3/16

(52) U.S. Cl. CPC H03M 1/38; H03H 11/04; G05F 3/16

(57) ABSTRACT

A transistor (M1) whose gate is capacitance-coupled to a wiring (L1) is connected between the wirings (L1, L2) connected to output nodes (OT1, OT2) outputting a reference voltage (VREF_OUT). A replica circuit (20) having a resistor (22) and a transistor (M2) connected in series is provided between the wirings (L1, L2). Gates of the transistors (M1, M2) are connected to each other. A differential amplifier (23) receives a voltage (V_RP) of a node (N1) between the resistor (22) and the transistor (M1) and a standard voltage (V_ID), and provides an output to the gate of the transistor (M2).

### CROSS-REFERENCE TO RELATED APPLICATIONS

This is a continuation of International Application No. PCT/JP2017/006354 filed on Feb. 21, 2017, which claims priority to Japanese Patent Application No. 2016-080597 filed on Apr. 13, 2016 The entire disclosures of these applications are incorporated by reference herein

### BACKGROUND

The present disclosure relates to a circuit to stabilize a reference voltage and, in particular, to a reference voltage stabilizing circuit suitable for an analog-to-digital (AD) converter.

AD converters are widely used for various fields of signal processing, and conversion accuracy of the AD converters is an important factor of their performance. A typical AD converter compares an input signal with a reference voltage to perform AD conversion. In order to maintain high conversion accuracy, it is significantly important to constantly maintain the accuracy of the reference voltage. The accuracy of the AD conversion would often deteriorate when mV order noise is superimposed on the reference voltage, depending on applications of the AD converters. Hence, in order to keep the reference voltage from swinging because of, for example, disturbance noise or noise generated from the AD converter itself, it is important to stabilize the reference voltage.

A known reference voltage stabilizing circuit (see, for example, FIG. 1 in WO 2012/157155) includes a transistor provided between wirings to supply a reference voltage. A constant bias voltage is applied to the gate of this transistor, and the gate is capacitance-coupled to one of the wirings. In this circuit configuration, the transistor conducts a constant current (hereinafter referred to as “an operating current” according to circumstances) when the reference voltage is stable (i.e., a steady state). When such a load circuit as the AD converter quickly draws in current and the reference voltage suddenly drops, a gate voltage of the transistor drops along with the drop of the reference voltage. The drop of the gate voltage reduces the operating current, and increases a current to be supplied to the load circuit. As a result, the reference voltage immediately recovers.

However, the operating current in the reference voltage stabilizing circuit could vary due to production process, power supply voltage, and temperature (PVT) variation. Thus, a level of the voltage drop in the reference voltage stabilizing circuit varies, causing variation in a value of the reference voltage.

In order to overcome such a problem, WO 2012/157155 discloses in FIG. 8 a reference voltage stabilizing circuit capable of maintaining the reference voltage against, for example, disturbance noise, and of coping with the PVT variation. In this configuration, the reference voltage to be output from the reference voltage stabilizing circuit is fed back to a regulator. When the reference voltage drops, the regulator increases a current to be supplied to the reference voltage stabilizing circuit.

The configuration in FIG. 8 of the WO 2012/157155 could stabilize the reference voltage to be output from the reference voltage stabilizing circuit; however, the configuration cannot reduce the variation in the operating current in the reference voltage stabilizing circuit. For example, when the operating current becomes large due to the PVT variation, the voltage in the reference voltage stabilizing circuit drops further, followed by the drop in the reference voltage. In this case, the regulator to which the reference voltage is fed back operates to increase the current to be supplied to the reference voltage stabilizing circuit. As a result, the reference voltage rises. In this case, however, the operating current is still large, and not reduced.

If the operating current is large, the power consumption of the circuit inevitably increases. Meanwhile, if the operating current is small, a decrease is observed in the amount of the current to be supplied to the load circuit when the reference voltage drops. As a result, the recovery of the reference voltage becomes slow, causing a decrease in stabilization capability of the reference voltage. In other words, the operating current in the reference voltage stabilizing circuit is beneficially stable, regardless of the PVT variation.

The present disclosure intends to reduce variation of a reference voltage, as well as of an operating current, in a reference voltage stabilizing circuit.

### SUMMARY

In an aspect of the present disclosure, a reference voltage stabilizing circuit includes: a first output node and a second output node, the first and second output nodes outputting a reference voltage; a first wiring connected to the first output node and a second wiring connected to the second output node, the first and second wirings receiving, as an input, a source voltage for the reference voltage; a first transistor connected between the first and second wirings; a capacitor connected between the first wiring and a gate of the first transistor; a replica circuit provided between the first and second wirings, and including a resistor and a second transistor connected in series, the second transistor having a gate connected to the gate of the first transistor; and a differential amplifier having: a first input connected to a first node between the resistor and the second transistor; a second input receiving a standard voltage; and an output connected to the gate of the second transistor.

According to this aspect, the first transistor is connected between the first wiring and the second wiring respectively connected to the first output node and the second output node outputting the reference voltage. The gate of the first transistor is capacitance-coupled to the first wiring. Provided between the first and second wirings is the replica circuit including the resistor and the second transistor connected in series. The gates of the first and second transistors are connected to each other. The differential amplifier receives the standard voltage and the voltage of the first node between the resistor and the second transistor included in the replica circuit, and provides an output to the gate of the second transistor. When an operating current of the first transistor increases because of, for example, PVT variation, the voltage of the first node drops in response to the drop of the reference voltage. Hence, the differential amplifier decreases the output; that is the gate voltage of the second transistor. Accordingly, the gate voltage of the first transistor also drops. Hence, the operating current of the first transistor decreases. Meanwhile, when an operating current of the first transistor decreases, the voltage of the first node rises in response to the rise of the reference voltage. Hence, the differential amplifier increases the output; that is the gate voltage of the second transistor. Accordingly, the gate voltage of the first transistor also rises. Hence, the operating current of the first transistor increases. Such operations reduce variation of the operating current of the first transistor. Such features make it possible to curb the reduction of stability in the reference voltage, as well as to curb an increase in power consumption.

The reference voltage stabilizing circuit according to the present disclosure can reduce variation of an operating current, as well as of a reference voltage. Such features make it possible to curb an increase in power consumption of an integrated circuit and reliably recover a dropped reference voltage.

### BRIEF DESCRIPTION OF THE DRAWINGS

FIG. 1 is a block diagram of a reference voltage stabilizing circuit according to Embodiment 1.

FIG. 2A illustrates a configuration example of a resistor. FIG. 2B illustrates a configuration example of a resistor,

FIG. 3 illustrates a configuration example of a voltage generation circuit.

FIG. 4 is a timing diagram illustrating a basic operation of the reference voltage stabilizing circuit.

FIG. 5 illustrates a configuration example in which multiple subsequent-stage circuits are provided,

FIG. 6A illustrates another configuration example of a previous-stage circuit. FIG. 6B illustrates another configuration example of a previous-stage circuit.

FIG. 7 illustrates another configuration of the reference voltage stabilizing circuit according to Embodiment 1.

FIG. 8 is a block diagram of a reference voltage stabilizing circuit according to Embodiment 2.

FIG. 9 is a block diagram of a reference voltage stabilizing circuit according to Embodiment 3.

FIG. 10 illustrates still another configuration of the reference voltage stabilizing circuit according to Embodiment 3.

### DETAILED DESCRIPTION

Embodiments will be described in detail with reference to the drawings.

### Embodiment 1

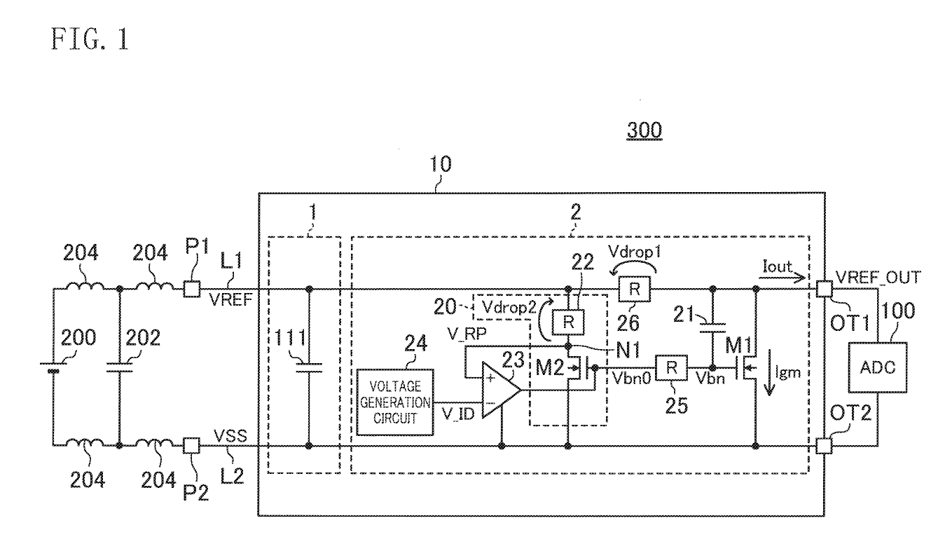

FIG. 1 illustrates a configuration of a reference voltage stabilizing circuit according to Embodiment 1. A reference voltage stabilizing circuit 10 outputs a reference voltage VREF_OUT from an output node OT1. The reference voltage VREF_OUT is supplied to an AD converter 100; that is, an example of a load circuit. An example of the AD converter 100 is a successive-approximation AD converter. Both the reference voltage stabilizing circuit 10 and the AD converter 100 are mounted on an integrated circuit 300. The reference voltage stabilizing circuit 10 receives, as an input, a voltage VREF via a wiring L1 and, as another input, a voltage VSS with a wiring L2 as source voltages for the reference voltage VREF_OUT. From an external power source 200, for example, the voltage VREF is supplied via an I/O pin P1 and the voltage VSS is supplied via an I/O pin P2. The wiring L1 is connected to the output node OT1 and the wiring L2 is connected to an output node OT2. The reference voltage stabilizing circuit 10 outputs the reference voltage VREF_OUT from the output nodes OT1 and OT2. The reference voltage VREF_OUT is stable against variation of load on the AD converter 100.

The I/O pins P1 and P2 are provided with an external bypass capacitor 202 for removing noise superimposed on the voltages VREF and VSS to be supplied from the external power source 200. Elements 204 are parasitic inductances of the package of the integrated circuit 300. Note that the reference voltage stabilizing circuit 10 is beneficially provided close to the I/O in the integrated circuit 300; that is close to the I/O pins P1 and P2, to be able to supply a stable reference voltage VREF_OUT. Moreover, instead of the external power source 200, a regulator circuit installed in the integrated circuit 300 may supply the reference voltage stabilizing circuit 10 with the voltages VREF and VSS.

The reference voltage stabilizing circuit 10 includes a previous-stage circuit 1 and a subsequent-stage circuit 2. The previous-stage circuit 1 includes a capacitor element 111 connected between the wirings L1 and L2. The previous-stage circuit 1 is capable of removing noise to be superimposed on the reference voltage VREF_OUT.

The subsequent-stage circuit 2 includes: a transistor M1 connected between the wirings L1 and L2; and a capacitor 21 connected between the wiring L1 and the gate of the transistor M1. The transistor M1 here is an n-type metal-oxide semiconductor (MOS) transistor. The gate of the transistor M1 is capacitance-coupled to the wiring L1. Hence, a gate voltage Vbn of the transistor M1 varies depending on the variation of the reference voltage VREF_OUT. Moreover, the subsequent-stage circuit 2 includes a replica circuit 20, a differential amplifier 23, and a voltage generation circuit 24 all of which are provided between the wirings L1 and L2. The replica circuit 20 includes a resistor 22 and a transistor M2 connected in series. The transistor M2 has a gate connected to the gate of the transistor M1. The transistor M2 here is an n-type MOS transistor. Note that the gate of the transistor M2 is connected to the gate of the transistor M1 via a resistor 25. Such a configuration keeps a gate voltage Vbn0 of the transistor M2 from an effect of sudden AC-wise variation of the gate voltage Vbn of the transistor M1. DC-wise, the gate voltage Vbn0 of the transistor M2 is equal to the gate voltage Vbn of the transistor M1. The differential amplifier 23 has: an inverted input receiving a standard voltage V_ID generated by the voltage generation circuit 24; and a non-inverted input connected to a node N1 between the resistor 22 and the transistor M2. An output from the differential amplifier 23 is provided to the gate of the transistor M2.

The subsequent-stage circuit 2 further includes a separating resistor 26 provided on the wiring L1 between the replica circuit 20 and the transistor M1.

A voltage drop across the separating resistor 26 is referred to as a Vdrop1. A voltage drop across the resistor 22 included in the replica circuit 20 is referred to as a Vdrop2. In this case, device parameters of the resistor 22 and the transistor M2 are adjusted so that the relationship Vdrop1=Vdrop2 holds. Specifically, for example, the device parameters are adjusted so that a resistance ratio of the resistor 22 to the transistor M2 is equal to a resistance ratio of the separating resistor 26 to the transistor M1. Hence, a voltage V_RP of the node N1 is equal to the reference voltage VREF_OUT.

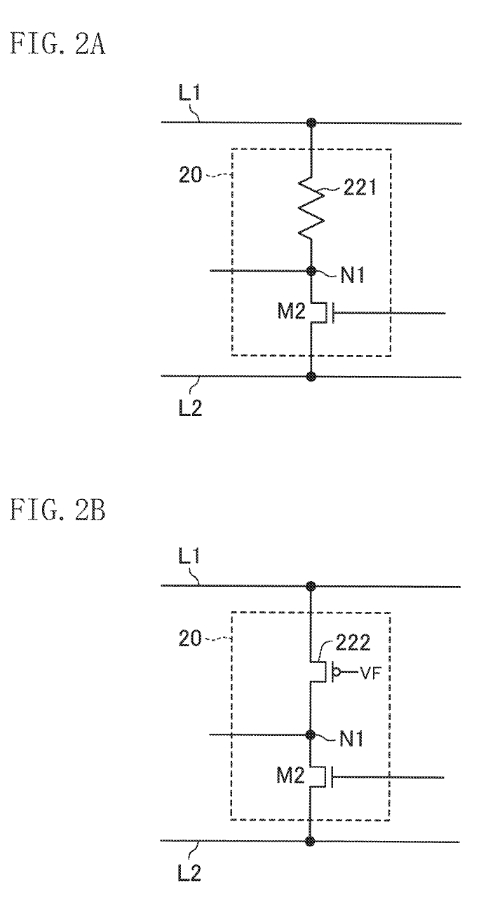

FIGS. 2A and 2B illustrate configuration examples of the resistor 22 in the replica circuit 20. As illustrated in FIG. 2A, the resistor 22 may be a resistive element 221 (i.e., a passive element). Alternatively, the resistor 22 may be a wire resistor made of a sufficiently long wiring. Moreover, as illustrated in FIG. 2B, the resistance 22 may be a transistor 222 a gate of which receives a bias voltage VF. The resistance 25 and the separating resistor 26 may also have configurations similar to the above.

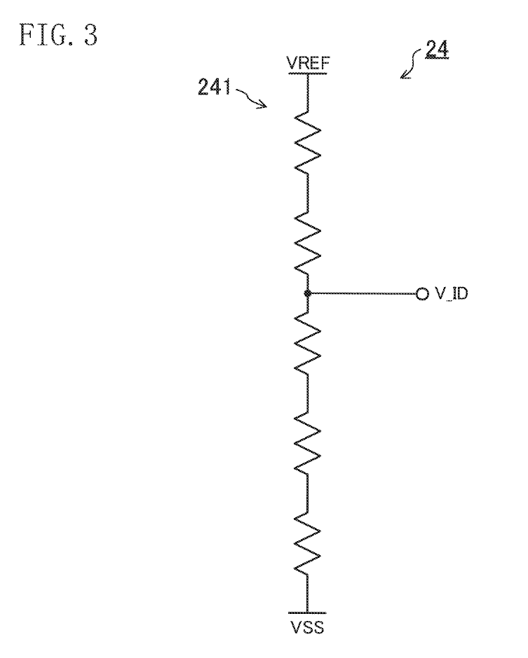

FIG. 3 illustrates a configuration example of the voltage generation circuit 24. In the configuration in FIG. 3, a resistor ladder 241 is provided between the voltages VREF and VSS. As illustrated in FIG. 3, the standard voltage V_ID is generated at any one of connection nodes of the resistors included in the resistor ladder 241. Other than the resistance ladder 241, an example of the voltage generation circuit 24 may be a band-gap reference circuit.

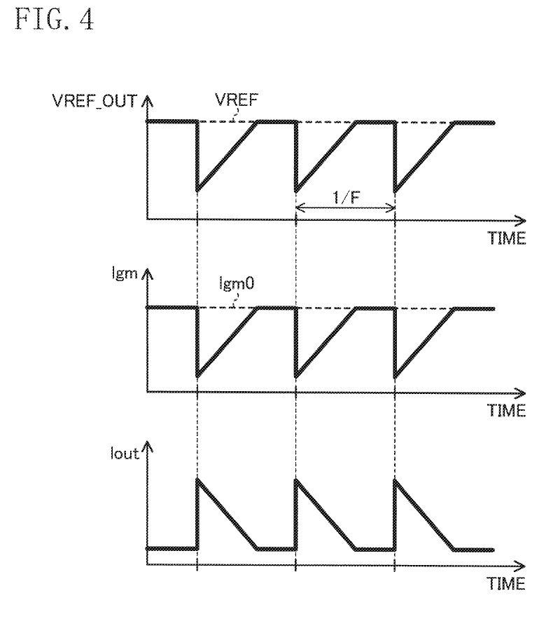

Described next is an operation of the reference voltage stabilizing circuit 10. FIG. 4 is a timing diagram illustrating a basic operation of the reference voltage stabilizing circuit 10. The AD convertor 100 discretely operates at an operating frequency F, and intermittently and suddenly draws in a current Iout at a period of I/F. When the current flows into the AD converter 100 and the reference voltage VREF_OUT suddenly drops, the gate voltage Vbn drops such that a current Igm flowing through the transistor M1 decreases. As a result, the current Lout to be supplied to the AD converter 100 increases such that the reference voltage VREF_OUT quickly recovers. Such an operation successfully stabilizes the reference voltage VREF_OUT.

Here, the current (operating current) Igm0, which flows thorough the transistor M1 in a steady state where the AD converter 100 does not draw in the current, could have variation caused by the so-called PVT variation. The configuration of this embodiment makes it possible to reduce the variation of the current Igm0.

Now, suppose the current Igm0 has increased due to the PVT variation. Then, the voltage drop Vdrop1 of the separating resistor 26 increases. As a result, the reference voltage VREF_OUT drops. Because of the replica circuit 20, the relationship VREF_OUT=V_RP holds. Hence, the voltage V_RP also drops in response to the drop of the reference voltage VREF_OUT. In response to the drop of the voltage V_RP; that is, a non-inverted input, the differential amplifier 23 decreases the output; that is, the gate voltage Vbn0 of the transistor M2. Accordingly, the gate voltage Vbn of the transistor M1 also drops. Hence, the current Igm0 decreases.

Furthermore, suppose the current Igm0 has decreased due to the PVT variation. Then, the voltage drop Vdrop1 of the separating resistor 26 decreases. As a result, the reference voltage VREF_OUT rises. Because of the replica circuit 20, the relationship VREF_OUT V_RP holds. Hence, the voltage V_RP also rises in response to the rise of the reference voltage VREF_OUT. In response to the rise of the voltage V_RP; that is, a non-inverted input, the differential amplifier 23 increases the output; that is, the gate voltage Vbn0 of the transistor M2. Accordingly, the gate voltage Vbn of the transistor M1 also rises. Hence, the current Igm0 increases.

Such operations reduce variation of the current Igm0.

In this embodiment, when the current Igm0 of the transistor M1 increases because of, for example, PVT variation, the voltage V_RP of the node NI drops in response to the drop of the reference voltage VREF_OUT. Accordingly, the differential amplifier 23 decreases the output; that is, the gate voltage Vbn0 of the transistor. Accordingly, the gate voltage Vbn of the transistor M1 also drops. Hence, the current Igm0 decreases. Meanwhile, when the current Igm0 of the transistor M1 decreases, the voltage V_RP of the node N1 rises in response to the rise of the reference voltage VREF_OUT. Accordingly, the differential amplifier 23 increases the output; that is the gate voltage Vbn0 of the transistor M2. Accordingly, the gate voltage Vbn0 of the transistor M1 also rises. Hence, the current Igm0 increases. These operations reduce variation of the current Igm0 of the transistor M1. Such features make it possible to curb the reduction of stability in the reference voltage, as well as to curb an increase in power consumption.

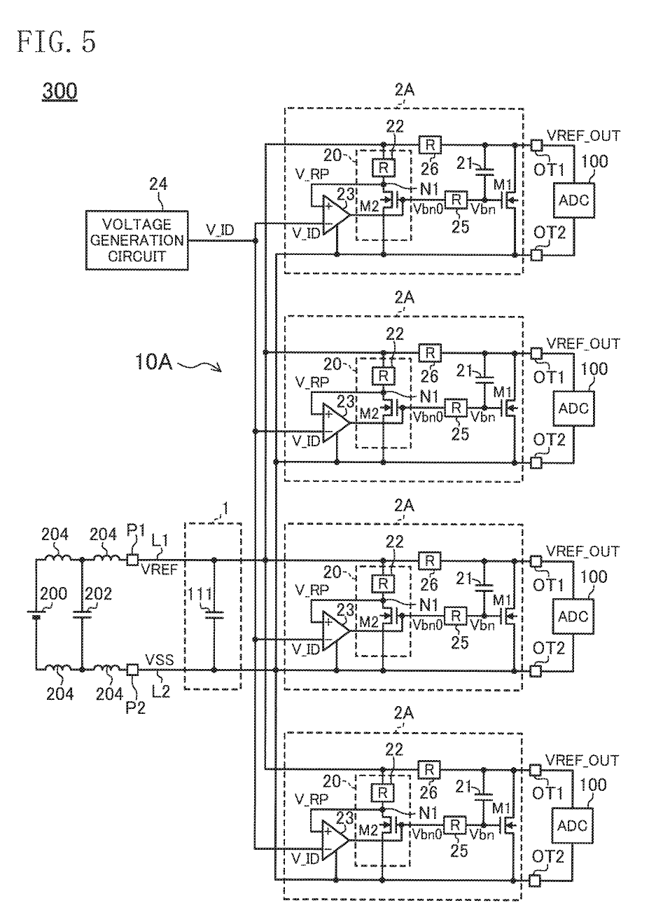

Moreover, the reference voltage stabilizing circuit may be modified so that multiple subsequent-stage circuits are connected to a single previous-stage circuit. FIG. 5 illustrates a configuration of a reference voltage stabilizing circuit 10A according to a modification. In this modification, four subsequent-stage circuits 2A are connected in common to one previous-stage circuit 1. Moreover, one voltage generation circuit 24 is connected to the four subsequent-stage circuits 2A. The standard voltage V_ID generated by the voltage generation circuit 24 is provided in common to the subsequent-stage circuits 2A. Each of the subsequent-stage circuits 2A supplies the stabilized reference voltage VREF_OUT to a corresponding one of AD converters 100. Note that examples of the multiple AD converters 100 include AD converters executing an interleave operation, AD converters arranged in parallel and converting a common analog input signal into a digital signal with a common operation clock, and AD converters each of which is independent and share a reference voltage alone.

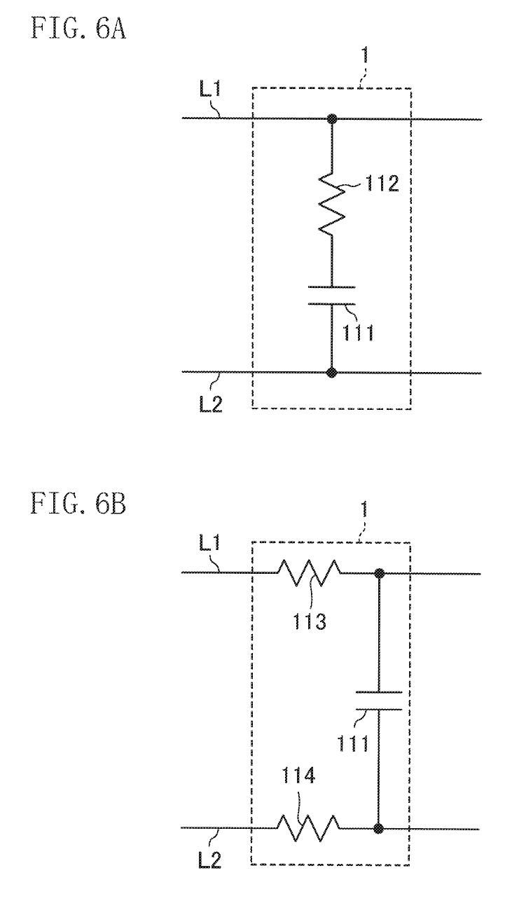

FIG. 6 illustrates another configuration example of the previous-stage circuit 1. In order to reduce a resonance phenomenon between the capacitor element 111 and the parasitic inductance 204, the capacitor element 111 and the resistive element 112 may be connected in series as illustrated in FIG. 6A. Alternatively, as illustrated in FIG. 6B, the resistive elements 113 and 114 are respectively provided to the wirings L1 and L2 forward of the capacitor element 111.

### Another Configuration Example 1

In the configuration in FIG. 1, the device parameters are adjusted so that the resistance ratio of the resistor 22 to transistor M2 of the replica circuit 20 is equal to a resistance ratio of the separating resistor 26 to the transistor M1. However, the present disclosure shall not be limited to this configuration.

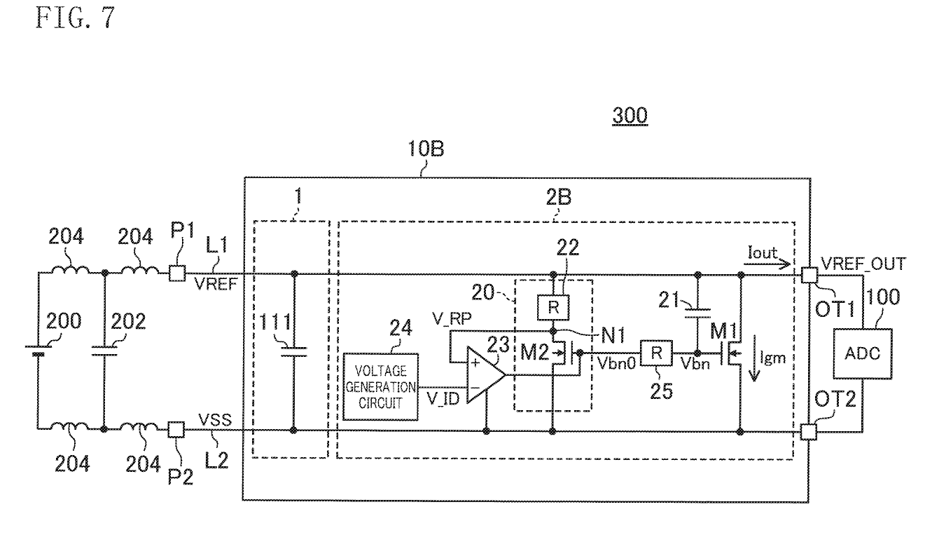

FIG. 7 illustrates another configuration of the reference voltage stabilizing circuit. In the configuration in FIG. 7, the separating resistor 26 is omitted from the wiring L1 in a subsequent-stage circuit 2B of a reference voltage stabilizing circuit 10B. Similar to the configuration in FIG. 1, the configuration in FIG. 7 can also reduce the variation of the current Igm0 of the transistor M1, using the voltage V_RP of the node N1. Specifically, when the current Igm0 increases because of the PVT variation, the reference voltage VREF_OUT drops. Accordingly, the voltage V_RP of the node N1 also drops. Because of the operation of the differential amplifier 23, the gate voltage Vbn0 of the transistor M2 drops. Accordingly, the gate voltage Vbn of the transistor M1 also drops, and the current Igm0 decreases. Meanwhile, when the current Igm0 decreases because of the PVT variation, the reference voltage VREF_OUT rises. Accordingly, the voltage V_RP of the node N1 also rises. Because of the operation of the differential amplifier 23, the gate voltage Vbn0 of the transistor M2 rises. Accordingly, the gate voltage Vbn of the transistor M1 also rises, and the current Igm0 increases.

Furthermore, in a configuration with the separating resistor 26, the resistance ratio of the resistor 22 to the transistor M2 does not have to be equal to the resistance ratio of the separating resistor 26 to the transistor M1. Note that, as seen in the configuration in FIG. 1, the device parameters may be adjusted so that the resistance ratio of the resistor 22 to the transistor M2 becomes equal to the resistance ratio of the separating resistor 26 to the transistor M1. Such an adjustment makes it possible to implement a circuit resistant to the PVT variation.

The configuration in FIG. 7 shows that, in the replica circuit 20, the resistor 22 is close to the wiring L1 and the transistor M2 is close to the wiring L2. Alternatively, the resistor 22 may be close to the wiring L2 and the transistor M2 may be close to the wiring L1.

### Embodiment 2

In Embodiment 2, a replica circuit in a reference voltage stabilizing circuit is implemented with a transistor and two resistors. Note that the constituent elements in common with those in Embodiment 1 might be omitted as appropriate.

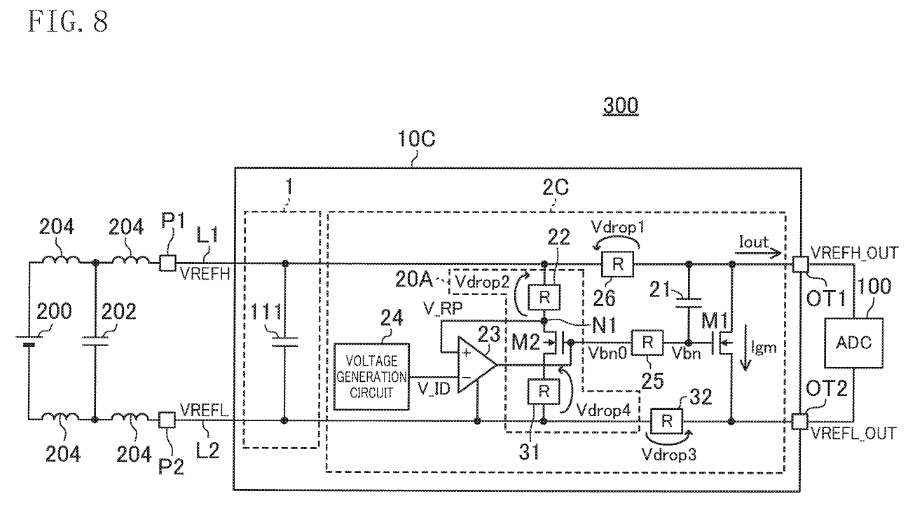

FIG. 8 illustrates a configuration of a reference voltage stabilizing circuit according to Embodiment 2. A reference voltage stabilizing circuit 10C outputs a reference voltage VREFH_OUT from the output node OT1 and a reference voltage VREFL_OUT from an output node OT2. The reference voltages VREFH_OUT and VREFL_OUT are supplied to the AD converter 100; that is, an example of a load circuit. An example of the AD converter 100 is a successive-approximation AD converter. Both the reference voltage stabilizing circuit IOC and the AD converter 100 are mounted on the integrated circuit 300. The reference voltage stabilizing circuit 10C receives, as an input, a voltage VREFH with the wiring L1 and, as another input, a voltage VREFL via the wiring L2. From the external power source 200, for example, the voltage VREFH is supplied via the I/O pin P1 and the voltage VREFL is supplied via the I/O pin P2. The wiring L1 is connected to the output node OT1 and the wiring L2 is connected to an output node OT2. The reference voltage stabilizing circuit 10C outputs a reference voltage VREFH_OUT from the output node OT1 and a reference voltage VREFL_OUT from the output node OT2. The reference voltages VREFH_OUT and VREFL_OUT are stable against variation of load on the AD converter 100.

A subsequent-stage circuit 2C includes: the transistor M1 connected between the wirings L1 and L2; and the capacitor 21 connected between the wiring L1 and the gate of the transistor M1. The transistor M1 here is an n-type metal-oxide semiconductor (MOS) transistor. The gate of the transistor M1 is capacitance-coupled to the wiring L1. Hence, the gate voltage Vbn of the transistor M1 varies depending on the variation of the reference voltage VREFH_OUT. Moreover, the subsequent-stage circuit 2C includes a replica circuit 20A, the differential amplifier 23, and the voltage generation circuit 24 all of which are provided between the wirings L1 and L2. The replica circuit 20A includes the resistor 22, the transistor M2, and a resistor 31 connected in series. The transistor M2 has a gate connected to the gate of the transistor M1 via the resistance 25. The transistor M2 here is an n-type MOS transistor. DC-wise, the gate voltage Vbn0 of the transistor M2 is equal to the gate voltage Vbn of the transistor M1. The differential amplifier 23 has: an inverted input receiving the standard voltage V_ID generated by the voltage generation circuit 24; and a non-inverted input connected to the node N1 between the resistor 22 and the transistor M2. An output from the differential amplifier 23 is provided to the gate of the transistor M2.

The subsequent-stage circuit 2C further includes: the separating resistor 26 provided on the wiring L1 between the replica circuit 20A and the transistor M1; and a separating resistor 32 provided on the wiring L2 between the replica circuit 20A and the transistor M1.

A voltage drop across the separating resistor 26 is referred to as the Vdrop1. A voltage drop across the resistor 22 included in the replica circuit 20A is referred to as the Vdrop2. Moreover, a voltage drop across the separating resistor 32 is referred to as a Vdrop3. A voltage drop across the resistor 31 included in the replica circuit 20A is referred to as a Vdrop4. In this case, device parameters of the resistor 22, the transistor M2, and the resistor 31 are adjusted so that the relationships Vdrop1=Vdrop2 and Vdrop3=Vdrop4 hold. Specifically, for example, the device parameters are adjusted so that a resistance ratio of the resistor 22 to the transistor M2 to the resistor 31 is equal to a resistance ratio of the separating resistor 26 to the transistor M1 to the separating resistor 32.

Similar to Embodiment 1, this embodiment makes it possible to reduce the variation of the current (operating current) Igm0, which flows thorough the transistor M1 in a steady state where the AD converter 100 does not draw in the current, using the voltage V_RP of the node N1. Specifically, when the current Igm0 increases because of the PVT variation, a difference voltage between the reference voltages VREFH_OUT and VREFL_OUT drops. Depending on the drop of this difference voltage, the voltage V_RP of the node N1 also drops. In response to the drop of the voltage V_RP; that is, a non-inverted input, the differential amplifier 23 decreases the output; that is, the gate voltage Vbn0 of the transistor M2.

Accordingly, the gate voltage Vbn of the transistor M1 also drops. Hence, the current Igm0 decreases. Meanwhile, when the current Igm0 decreases because of the PVT variation, the difference voltage between the reference voltages VREFH_OUT and VREFL_OUT rises. In response to the rise of the difference voltage, the voltage V_RP of the node N1 also rises. In response to the rise of the voltage V_RP; that is, a non-inverted input, the differential amplifier 23 increases the output; that is, the gate voltage Vbn0 of the transistor M2. Accordingly, the gate voltage Vbn of the transistor M1 also rises. Hence, the current Igm0 increases. Such operations reduce variation of the current Igm0.

Note that, in the configuration of FIG. 8, the device parameters are adjusted so that the resistance ratio of the resistor 22 to the transistor M2 to the resistor 31 is equal to the resistance ratio of the separating resistor 26 to the transistor M1 to the separating resistor 32. However, the present disclosure shall not be limited to this configuration. For example, either one of, or both of, the separating resistors 26 and 32 may be omitted. Alternatively, in a configuration with the separating resistors 26 and 32, the resistance ratio of the resistor 22 to the transistor M2 to the resistor 31 does not have to be equal to the resistance ratio of the separating resistor 26 to the transistor M1 to the separating resistor 32.

### Embodiment 3

In Embodiment 3, an assist circuit is provided for a reference voltage to recover more quickly. Note that the constituent elements in common with those in Embodiment 1 might be omitted as appropriate.

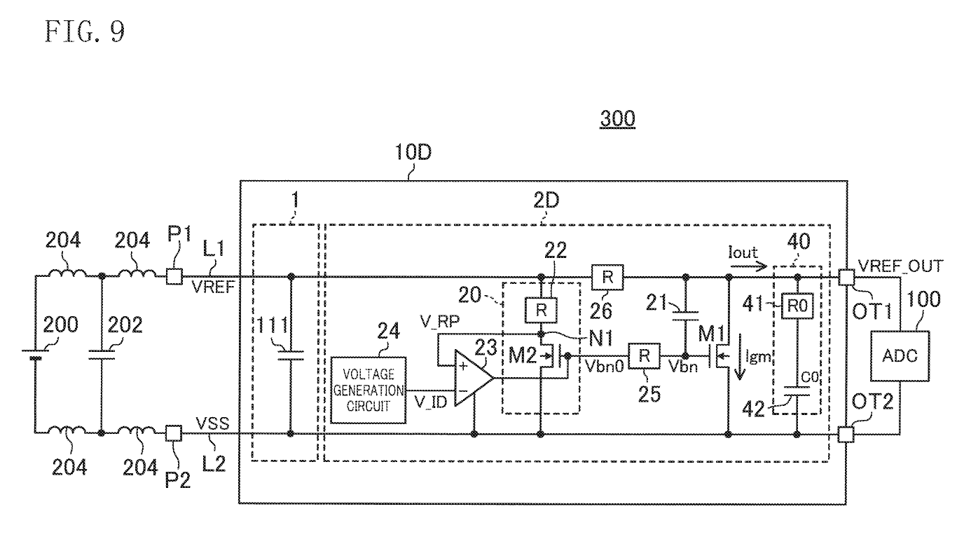

FIG. 9 illustrates a configuration of a reference voltage stabilizing circuit according to Embodiment 3. In a reference voltage stabilizing circuit 10D, a subsequent-stage circuit 2D includes an assist circuit 40 for the reference voltage VREF_OUT to recover more quickly. Other than the assist circuit 40, the subsequent-stage circuit 2D is the same in configuration as the subsequent-stage circuit 2 in FIG. 1.

The assist circuit 40 includes a resistor 41 and a capacitor 42 both connected in series between the wirings L1 and L2. The assist circuit 40 is provided closer to the output of the reference voltage stabilizing circuit 10D than the transistor M1 is. The impedance of the resistor 41 is set sufficiently large to the degree that the impedance of the capacitor 42 at the operating frequency F of the AD converter 100 can be ignored. Specifically, a relationship of the expression (1) below is satisfied where R0 is a resistance of the resistor 41 and C0 is a capacitance of the capacitor 42. Note that the resistance R0 is suitably ten times larger than the impedance of the capacitor 42 at the operating frequency F.

R0>>1/(2π×F×C0) (1)

In this case, when the reference voltage VREF_OUT suddenly drops, the assist circuit 40 supplies the AD converter 100 with charge, stored in the capacitor 42, as a current. In the assist circuit 40 here, resistant impedance is dominant. Hence, the amount of current to be supplied is determined by the resistance R0 of the resistor 41 and the voltage value of the reference voltage VREF_OUT. Hence, the assist circuit 40 continues to supply a large current until the reference voltage VREF_OUT recovers. Moreover, a terminal, of the capacitor 42, close to the resistor maintains a voltage higher than the reference voltage VREF_OUT. Hence, the current will not be supplied from the wiring L1 to the capacitor 42.

The assist circuit 40 executes such operations to promote the recovery of the dropped reference voltage VREF_OUT. Moreover, in an steady state where the AD converter 100 does not draw in the current, the capacitor 42 blocks a direct current so that unnecessary through-current is not generated.

Furthermore, in the case where the voltages VREF and VSS are provided from a regulator circuit built in the integrated circuit 300 to the reference voltage stabilizing circuit 10, the assist circuit may be provided to the regulator circuit.

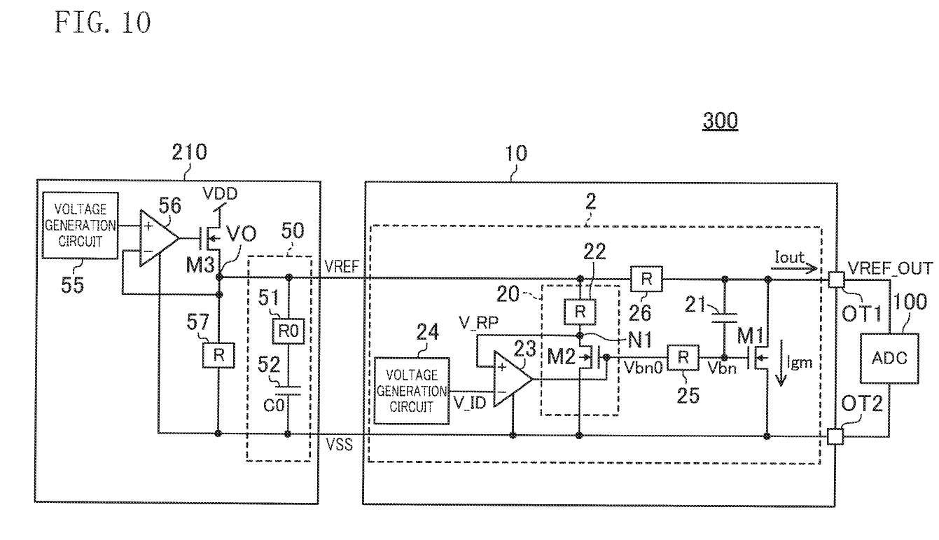

FIG. 10 illustrates a configuration in which the assist circuit is provided to a regulator circuit. Note that, in FIG. 10, the previous-stage circuit 1 in the reference voltage stabilizing circuit 10 is not shown. A regulator circuit 210 includes: an operational amplifier 56 receiving a voltage, generated by a voltage generation circuit 55, via a positive input; an output transistor (in a source follower structure) M3 connected between a power source VDD and an output node VO and receiving the output of the operational amplifier 56 via the gate; and a load resistor 57 connected between the output transistor M3 and a ground VSS. The output node VO is feedback-connected to a negative input of the operational amplifier 56. The regulator circuit 210 further includes an assist circuit 50 similar in configuration to the assist circuit 40. The assist circuit 50 includes a resistor 51 and a capacitor 52 connected in series between an output node VO and a ground VSS. The impedance of the resistor 51 is set sufficiently large to the degree that the impedance of the capacitor 52 at the operating frequency F of the AD converter 100 can be ignored.

In this configuration, too, the assist circuit 50 can promote the recovery of the dropped reference voltage VREF_OUT. Moreover, in a steady state where the AD converter 100 does not draw in the current, the capacitor 52 blocks a direct current so that unnecessary through-current is not generated.

Note that, as described in this embodiment, an assist circuit can be provided to a configuration other than that in FIG. 1.

For the sake of convenience, the AD converter 100 in the above description is, but not limited to, a successive-approximation AD converter. The AD converter 100 may be another type of AD converter discretely operating on a clock signal. Examples of such an AD converter include a pipeline AD converter, a flash AD converter, and a delta-sigma AD converter. Moreover, a load circuit receiving a reference voltage is not limited to the AD converter 100. Any given circuit may be the load circuit as long as the circuit refers to a reference voltage to operate.

The reference voltage stabilizing circuit according to the present disclosure can reduce variation of an operating current, as well as of a reference voltage. Hence, the reference voltage stabilizing circuit is useful for curbing an increase in power consumption of an integrated circuit and enhancing performance of an AD converter.

What is claimed is:

1. A reference voltage stabilizing circuit comprising:
a first output node and a second output node, the first and second output nodes outputting a reference voltage;
a first wiring connected to the first output node and a second wiring connected to the second output node, the first and second wirings receiving, as an input, a source voltage for the reference voltage;
a first transistor connected between the first and second wirings;
a capacitor connected between the first wiring and a gate of the first transistor;
a replica circuit provided between the first and second wirings, and including a resistor and a second transistor connected in series, the second transistor having a gate connected to the gate of the first transistor; and
a differential amplifier having: a first input connected to a first node between the resistor and the second transistor; a second input receiving a standard voltage; and an output connected to the gate of the second transistor.

2. The reference voltage stabilizing circuit of claim 1, further comprising
a separating resistor provided on the first wiring between the replica circuit and the first transistor,

3. The reference voltage stabilizing circuit of claim 2, wherein
a resistance ratio of the resistor to the second transistor included in the replica circuit is equal to a resistance ratio of the separating resistor to the first transistor.

4. The reference voltage stabilizing circuit of claim 2, further comprising
a second separating resistor provided on the second wiring between the replica circuit and the first transistor.

5. The reference voltage stabilizing circuit of claim 1, wherein
in the replica circuit, the resistor is provided closer to the first wiring and the second transistor is provided closer to the second wiring.

6. The reference voltage stabilizing circuit of claim 1, wherein
the replica circuit includes a second resistor connected in series to the second transistor and provided across from the resistor.

7. The reference voltage stabilizing circuit of claim 1, wherein
the gate of the second transistor is connected to the gate of the first transistor via the second resistor.

8. The reference voltage stabilizing circuit of claim 1, further comprising
a voltage generation circuit generating the standard voltage.

9. The reference voltage stabilizing circuit of claim 1, further comprising
a previous-stage circuit including a second capacitor connected between the first and second wirings.

10. The reference voltage stabilizing circuit of claim 9, further comprising
subsequent-stage circuits each including the first transistor, the capacitor, the replica circuit, and the differential amplifier, wherein
the subsequent-stage circuits are connected in common e previous-stage circuit.

11. The reference voltage stabilizing circuit of claim 10, further comprising
a voltage generation circuit generating the standard voltage, wherein
the standard voltage generated by the voltage generation circuit is provided in common to the subsequent-stage circuits.

12. The reference voltage stabilizing circuit of claim 1, further comprising
an assist circuit provided closer to an output of the reference voltage stabilizing circuit than the first transistor is, and including a second resistor and a second capacitor provided between the first and second wirings and connected in series.

13. The reference voltage stabilizing circuit of claim 1, further comprising
a regulator circuit generating the source voltage, wherein
the regulator circuit includes
an assist circuit provided between wirings supplying the source voltage, and including a second resistor and a second capacitor connected in series.

14. An integrated circuit comprising: the reference voltage stabilizing circuit of claim 1, and
an analog-to-digital conversion circuit operating by receiving a reference voltage output from the reference voltage stabilizing circuit.
